(19) United States
(12) Patent Application Publication
(10) Pub. No.: US 2024/0234173 A1
(43) Pub. Date: Jul. 11, 2024

(54) SUBSTRATE PROCESSING APPARATUS AND SUBSTRATE PROCESSING METHOD

(71) Applicant: SHIBAURA MECHATRONICS CORPORATION, Kanagawa (JP)

(72) Inventor: Hiroki KOYAMA, Kanagawa (JP)

(21) Appl. No.: 18/612,678

(22) Filed: Mar. 21, 2024

Related U.S. Application Data
(63) Continuation of application No. PCT/JP2022/035858, filed on Sep. 27, 2022.

(30) Foreign Application Priority Data
Sep. 28, 2021 (JP) 2021-158151

(51) Int. Cl. H01L 21/67; H01L 21/687

(52) U.S. Cl. CPC H01L 21/6708; H01L 21/67051; H01L 21/6715; H01L 21/68764

(57) ABSTRACT

According to one embodiment of the present disclosure, a substrate processing apparatus includes a rotor that holds and rotates a substrate, a first processing liquid supply unit that supplies a first processing liquid for etching to a processing target surface of the substrate that is being rotated by the rotor, thereby etching the processing target surface of the substrate, and a second processing liquid supply unit that supplies a second processing liquid for oxidation to the processing target surface of the substrate that is being rotated by the rotor, thereby forming an oxide film, consecutively to the etching by the supplying of the first processing liquid.

### CROSS-REFERENCE TO RELATED APPLICATIONS

This application is a continuation application of International Patent Application No. PCT/JP2022/035858, filed on Sep. 27, 2022, which claims priority to Japanese Patent Application No. 2021-158151, filed on Sep. 28, 2021, with the Japan Patent Office, all of which are incorporated herein in their entireties by reference.

### TECHNICAL FIELD

The present disclosure relates to a substrate processing apparatus and a substrate processing method.

### BACKGROUND

As a wet etching apparatus for etching a film laminated onto a substrate such as a semiconductor wafer with a processing liquid, a batch-type substrate processing apparatus exists that immerses multiple sheets of substrate in the processing liquid at once. Such a batch-type substrate processing apparatus is highly productive because it may process multiple sheets of substrate at once.

However, in the batch-type substrate processing apparatus, since multiple sheets of substrate are immersed in a processing liquid under common conditions, it is difficult to precisely adjust the depth of etching for each substrate due to differences in thickness of films formed on each of substrates. Therefore, a single substrate processing type apparatus is being used for processing substrates one by one by supplying an etching processing liquid near the center of rotation of the substrate while rotating the substrate and spreading the processing liquid to a surface of the substrate.

As for the etching processing liquid, acid-based liquids such as hydrofluoric acid, phosphoric acid, and sulfuric acid are used. For example, there is provided a substrate processing apparatus that uses phosphoric acid as a processing liquid when etching a nitride film as a target film, in a substrate where a natural oxide film (SiO₂) is formed on polysilicon (Poly-Si) of a silicon wafer by contact with the atmosphere and the nitride film (SiN) is stacked on the oxide film (see, e.g., Japanese Patent Publication No. 2012-074601).

In the substrate processing apparatus which performs etching with a processing liquid containing phosphoric acid, it is necessary to selectively etch an oxide film and a nitride film, for example, to etch the nitride film while suppressing etching of the oxide film below the nitride film. To cope with this, there is a method of incorporating colloidal silica into the processing liquid. This method reduces the overall etching rate, making it more difficult for the oxide film to be etched.

### SUMMARY

However, even by this method of reducing the overall etching rate, an oxide film is etched to some extent. In particular, in a portion where the oxide film under a nitride film is thin, the oxide film may be removed entirely, exposing polysilicon under the oxide film. In addition, in a portion where no oxide film is formed under the nitride film in the first place, the polysilicon is exposed by etching the nitride film.

After the etching, a rinse with hot de-ionized water or APM processing with an APM processing liquid (a mixture of ammonia water and hydrogen peroxide) which is an alkaline solution is performed to conduct cleaning for removing a processing liquid containing phosphoric acid. However, when the cleaning is performed in a state where the polysilicon is exposed, the exposed polysilicon is etched by an action of the heat of the hot de-ionized water or the APM processing liquid. That is, portions other than a target film to be etched are etched, leading to product defects.

Embodiments of the present disclosure are proposed to solve the above-mentioned problems, and an aspect of the present disclosure is to provide a substrate processing apparatus and a substrate processing method, capable of suppressing product defects by protecting a portion exposed after etching with an oxide film.

A substrate processing apparatus according to an embodiment of the present disclosure includes a rotor that holds and rotates a substrate, a first processing liquid supply unit that supplies a first processing liquid for etching to a processing target surface of the substrate that is being rotated by the rotor, thereby etching the processing target surface of the substrate, and a second processing liquid supply unit that supplies a second processing liquid for oxidation to the processing target surface of the substrate that is being rotated by the rotor, thereby forming an oxide film, after the etching by the supplying of the first processing liquid.

In the substrate processing method according to an embodiment of the present disclosure, the substrate is held and rotated by the rotor, the first processing liquid for etching is supplied to the processing target surface of the substrate that is being rotated by the rotor, and the second processing liquid for oxidation is supplied to the processing target surface of the substrate that is being rotated by the rotor.

According to embodiments of the present disclosure, it is possible to provide a substrate processing apparatus and a substrate processing method, capable of suppressing product defects by protecting a portion exposed after etching with an oxide film.

The above summary is for illustrative purposes only and is not intended to be limiting in any way. In addition to the illustrative aspects, embodiments and features described above, additional aspects, embodiments and features will become apparent by reference to the drawings and the detailed description below.

### BRIEF DESCRIPTION OF THE DRAWINGS

FIG. 1 is a diagram illustrating an overall configuration of a substrate processing apparatus according to an embodiment.

FIGS. 2A to 2C are explanatory view illustrating oxide film formation of the substrate processing apparatus according to an embodiment.

FIG. 3 is a partial cross-sectional side view illustrating an etching device of the substrate processing apparatus of FIG. 1.

FIGS. 4A and 4B are plan views illustrating an operation of a holding unit of the etching device of FIG. 3.

FIG. 5 is a plan view illustrating a processing liquid holding unit of the etching device of FIG. 3.

FIGS. 6A and 6B are explanatory views illustrating a second processing liquid supply operation of the etching device of FIG. 3.

FIG. 7 is a flowchart illustrating a process sequence of the substrate processing apparatus according to an embodiment.

FIG. 8 is a view illustrating a modification of a substrate processing apparatus according to an embodiment.

### DESCRIPTION OF EMBODIMENTS

In the following detailed description, reference is made to the accompanying drawings, which form a part of the present disclosure. The exemplary embodiments described in the detailed description, drawings, and claims are not intended to be limiting. Other embodiments may be utilized, and other changes may be made, without departing from the scope or spirit of the subject matter presented herein.

Hereinafter, embodiments of the present disclosure will be described with reference to the drawings.

### [Outline]

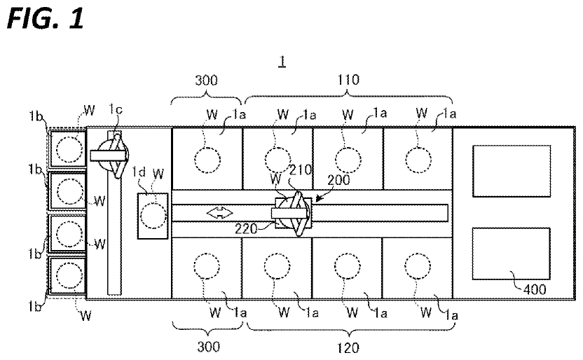

As illustrated in FIG. 1, a substrate processing apparatus 1 of this embodiment is a single substrate processing type apparatus which includes a plurality of chambers 1a configured to accommodate devices for performing various processes and which performs processing of a plurality of substrates W accommodated in a cassette (FOUP) 1b and transferred, one by one in each chamber 1a during an overall process. The substrates W that are unprocessed are taken out one by one from the cassette 1b by a transfer robot 1c, temporarily disposed in a buffer unit 1d, and then, transferred to and processed in each chamber 1A by various devices described below.

The substrate processing apparatus 1 includes an etching device 110, a cleaning device 120, a transfer device 200, a drying device 300, and a control device 400. The etching device 110 is a device that removes a portion of a target film by supplying a processing liquid for etching to a processing target surface of the substrate W that is rotating, and leaves a required film. The cleaning device 120 performs cleaning by supplying a processing liquid for cleaning to the processing target surface of the substrate

W that has been etched in the etching device 110. As will be described later, cleaning is also performed in the etching device 110 by supplying of a cleaning liquid, but this cleaning is different from the cleaning of the cleaning device 120, which is performed in chambers (second chambers) 1a that are different from chambers (first chambers) 1a of the etching device 110.

The transfer device 200 transfers the substrate W between the buffer unit 1d and each chamber 1a, and between each of the chambers 1a. For example, the transfer device 200 transfers the substrate W that has been processed in the etching device 110 to the cleaning device 120 and transfers the substrate W that has been cleaned in the cleaning device 120 to the drying device 300. The transfer device 200 also has a robot hand 210 for gripping the substrate W, and a transfer robot 220 for moving the robot hand 210. The drying device 300 performs drying by heating the cleaned substrate W while rotating the substrate W. The control device 400 controls each of the above devices.

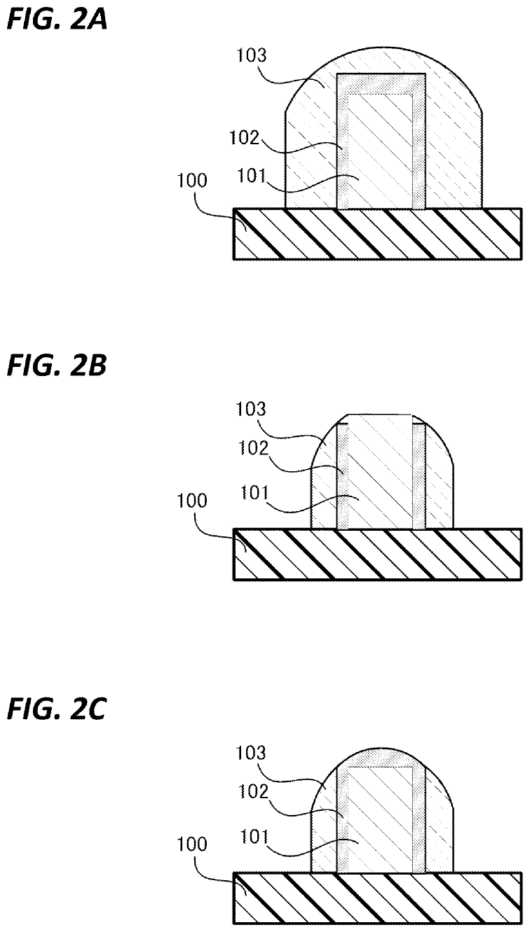

In addition, the substrate W that is processed according to this embodiment is, for example, a semiconductor wafer. Hereinafter, a surface of the substrate W on which patterns are formed is referred to as the processing target surface. As illustrated in FIG. 2A, the processing target surface has a portion where polysilicon 101, a silicon oxide film 102, and a silicon nitride film 103 are overlapped in sequence on the silicon wafer 100. Hereinafter, the silicon oxide film 102 is simply referred to as the oxide film 102, and the silicon nitride film 103 is simply referred to as the nitride film 103.

The target film to be etched is the nitride film 103. The oxide film 102 is a film that is naturally formed through contact with the atmosphere and functions as a protective film that protects the polysilicon 101, but there is also a place where the oxide film 102 is not formed. It is desirable that the etching is performed on a portion of the nitride film 103, and the etching of the oxide film 102 is suppressed as much as possible, so that the preserved oxide film 102 protects the polysilicon 101 during cleaning. However, as described above, the oxide film 102 may be easily removed during etching (see FIG. 2B). Additionally, a target protective layer is not limited to the polysilicon 101 and may be epitaxial silicon. When a target protective layer is the silicon wafer 100, the overall silicon is targeted.

As a processing liquid (a first processing liquid) for etching, an aqueous solution containing phosphoric acid (HPO) (hereinafter, referred to as phosphoric acid solution) is used. In this embodiment, after etching, a processing liquid (a second processing liquid) for oxide film formation is supplied to the processing target surface of the rotating substrate W, thereby oxidizing the processing target surface. This serves to maintain a function as a protective film by supplementing the removed oxide film 102 (see FIG. 2C) and to reinforce a function as a protective film by forming the oxide film 102 that was not present. As the second processing liquid for oxide film formation, hydrogen peroxide (H₂O₂) or ozone (O₃) water is used.

In the cleaning device 120, an alkaline cleaning liquid (APM), a de-ionized water (DIW) and a volatile solvent (IPA) are used as processing liquids for cleaning (rinse). The APM is a chemical liquid where ammonia water and hydrogen peroxide are mixed, and is used to remove residual organic materials. The DIW is used to wash away the APM remaining on the processing target surface of the substrate W after APM processing. Since the IPA has surface tension lower than that of the DIW and volatility higher than that of the DIW, the IPA is used to replace the DIW and reduce pattern collapse due to the surface tension. Additionally, the etching device 110 of this embodiment uses carbonated water (COW) for cleaning before the etching and uses hot de-ionized water (Hot DIW) for cleaning after oxide film formation.

Each processing parts of this embodiment processes the processing target surface of the substrate W by supplying a processing liquid to the processing target surface while rotating the substrate W together with a rotor 10. Hereinafter, the etching device 110 will be mainly described.

### [Etching Device]

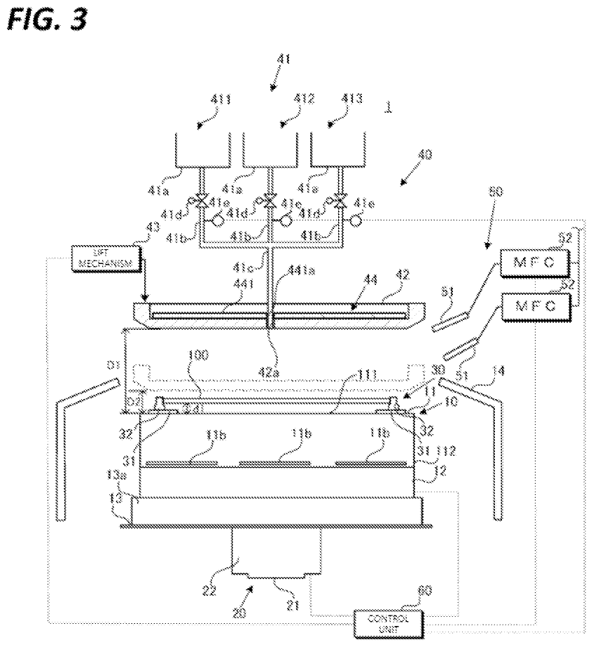

As illustrated in FIGS. 3 to 5, the etching device 110 includes the rotor 10, a rotation mechanism 20, a holding unit 30, a first processing liquid supply unit 40, a second processing liquid supply unit 50, and a control unit 60. In addition, in FIG. 3, the chamber 1a (the first chamber) which accommodates the rotor 10, the rotation mechanism 20, and the holding unit 30 and in which etching and oxide film formation are performed, is not illustrated.

### (Rotor)

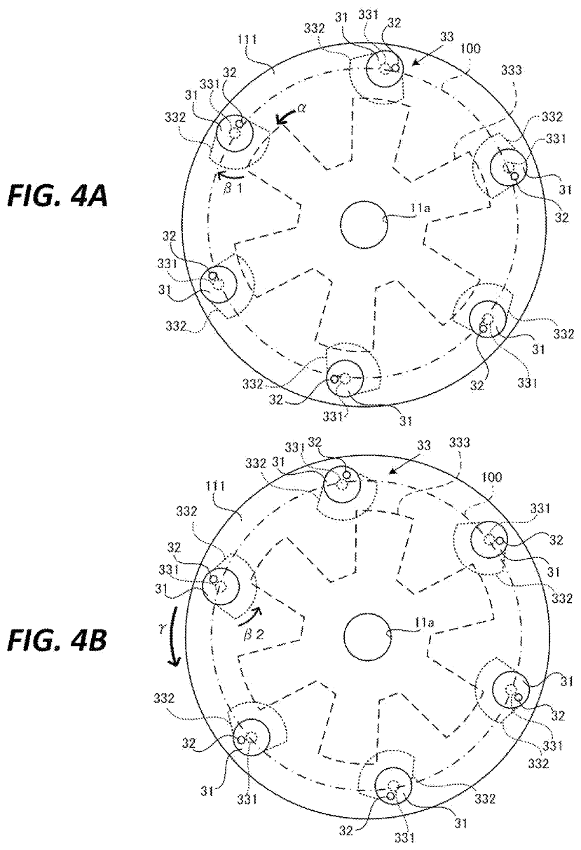

The rotor 10 has a facing surface 111 facing the substrate W held on the holding unit 30 while leaving a space between the facing surface 111 and the substrate W, and is installed rotatably with the holding unit 30. The rotor 10 has a table 11 and a base 12. The table 11 has a cylindrical shape in which one end is blocked by the facing surface 111. The facing surface 111 is a circular face with a diameter larger than that of the substrate W. In the center of the facing surface 111, a circular through-hole 11a is formed (see FIG. 4). In a side surface 112 of the table 11, outlets 11b are formed, which are through-holes for discharging processing liquids.

The base 12 is a cylindrical member having the same diameter as that of the table 11 and connected to a side of the table 11 opposite to the facing surface 111. The base 12 is a member having a structure for supporting the table 11. The table 11 and the base 12, which constitute the rotor 10, are formed of a material resistant to the processing liquid. For example, the rotor 10 may be formed of a fluorinated resin such as PTFE or PCTFE.

In addition, the rotor 10 is rotatably installed on a fixed base 13 fixed to a mounting surface (not illustrated) or to a trestle installed on the mounting surface by the rotation mechanism 20 to be described later. On the fixed base 13, a protective wall 13a is installed. The protective wall 13a is a double cylindrical wall, which is concentric with the base 12 and erected on the fixed base 13, and covers a lower edge of the base 12 in a non-contact manner. This forms a labyrinth structure that is a curved pathway, between the protective wall 13a and the base 12, which makes it difficult for the processing liquid running down an outer wall of the base 12 to enter an interior of the base 12.

Furthermore, around the rotor 10 in the chamber 1a, a cup 14 is installed to receive various processing liquids that are scattered from the rotating substrate W, from surroundings of the substrate W.

### (Rotation Mechanism)

The rotation mechanism 20 is a mechanism that rotates the rotor 10. The rotation mechanism 20 has a fixed shaft 21 and a drive source 22. The fixed shaft 21 is a cylindrical member disposed coaxially with the rotor 10. A lower end of the fixed shaft 21 is fixed to the fixed base 13 together with the drive source 22 to be described later.

The drive source 22 is a hollow motor having a hollow rotator and a stator that rotates the hollow rotator. The drive source 22 is fixed to the fixed base 13 together with the fixed shaft 21. The drive source 22 applies electric power to a coil of the stator and causes the rotator to rotate, so that the table 11 rotates together with the base 12.

### (Holding Unit)

The holding unit 30 holds the substrate W to be parallel to the facing surface 111 and spaced apart from the facing surface 111. As illustrated in FIG. 4, the holding unit 30 has pivoting members 31, holding pins 32, and a driving mechanism 33. The pivoting members 31 are cylindrical members disposed in plural numbers at equal intervals along a periphery of the substrate W. The pivoting member 31 is installed pivotably about an axis parallel to the fixed shaft 21. An upper surface of the pivoting member 31 is exposed from the facing surface 111.

The holding pin 32 is erected and installed at a position that is eccentric from a center of pivoting in the upper surface of the pivoting member 31. The holding pin 32 has a cylindrical shape and is provided with a concave portion into which an edge of the substrate W is inserted. The holding pin 32 moves between a holding position (see FIG. 4A) where the holding pin 32 holds the substrate W as the the holding pin 32 contacts the edge of the substrate W according to pivoting of the pivoting member 31, and a release position (see FIG. 4B) where the holding pin 32 releases the substrate W as the holding pin 32 moves away from the edge of the substrate W.

The driving mechanism 33 moves the holding pin 32 between the holding position and the release position by pivoting the pivoting member 31. The driving mechanism 33 includes a drive shaft 331, a small gear 332, and a large gear 333.

The drive shaft 331 is a cylindrical member that is installed coaxially with an axis of pivoting of the pivoting member 31 on a side opposite to the upper surface of the pivoting member 31. The small gear 332 is a sector gear that is installed at an end of the drive shaft 331 on an opposite side to the pivoting member 31. The large gear 333 is a gear in which gear grooves are formed intermittently to correspond to the small gears 332. The large gear 333 is rotatably formed in the base 12 by a bearing (not illustrated). The large gear 333 is provided with six convex portions that are formed at predetermined intervals in a circumferential direction with intervals corresponding to the small gears 332. In an outer peripheral surface of a front end of each convex portion, the gear groove is formed, which engages with the small gear 332.

The large gear 333 is pressed in a direction of rotation (a counterclockwise direction) indicated by an arrow α in FIG. 4A by a pressing member such as a spring (not illustrated). Accordingly, since the small gear 332 is pressed in a clockwise direction indicated by an arrow β1, the pivoting member 31 interlocks with the pivoting of the small gear 332, so that the holding pin 32 moves in a center direction of the rotor 10 and is held in the holding position that is in contact with the substrate W. Furthermore, when processing the substrate, in a state where this holding position is held, the pivoting member 31, the drive shaft 331, the holding pin 32, the small gear 332, and the large gear 333 rotate together with the rotor 10.

In addition, rotation of the large gear 333 is stopped by a stopper mechanism (not illustrated). In a state where the rotation of the large gear 333 is stopped, when the rotor 10 is rotated in a direction of an arrow γ, as illustrated in FIG. 4B, the small gear 332 engaged with the large gear 333 whose rotation is stopped, pivots in a counterclockwise direction indicated by an arrow β2. Since the pivoting member 31 rotates correspondingly, the holding pin 32 moves away from the edge of the substrate W and comes to the release position.

### (First Processing Liquid Supply Unit)

The first processing liquid supply unit 40, as illustrated in FIG. 3, performs etching by supplying a first processing liquid for etching to the processing target surface of the substrate W, i.e., a surface opposite to the facing surface 111 of the substrate W held on the holding unit 30. The first processing liquid supply unit 40 includes a processing liquid supply mechanism 41, a processing liquid holding unit 42, a lift mechanism 43, and a heating unit 44.

The processing liquid supply mechanism 41 includes supply units 411, 412, and 413 for supplying three types of processing liquids. The supply unit 411 supplies carbonated water as a processing liquid. The supply unit 412 supplies a phosphoric acid solution as a processing liquid. The phosphoric acid solution is the first processing liquid for etching. The supply unit 413 supplies hot de-ionized water. The supply units 411, 412, and 413 have processing liquid tanks 41a for storing each processing liquid. In addition, the carbonated water and the hot de-ionized water are cleaning liquids for cleaning (rinse). For this reason, a part of the first processing liquid supply unit 40 of this embodiment is configured as a cleaning liquid supply.

From each of the processing liquid tanks 41a, individual delivery pipes 41b are connected in parallel to a processing liquid supply pipe 41c. A front end of the processing liquid supply pipe 41c faces the substrate W held on the holding unit 30. Accordingly, the processing liquid from each processing liquid tank 41a is supplied to the surface of the substrate W through each individual delivery pipe 41b and the processing liquid supply pipe 41c.

A flow rate adjustment valve 41d and a flow meter 41e are installed on each individual delivery pipe 41b. By adjusting each flow rate adjustment valve 41d, the amount of the processing liquid flowing into the processing liquid supply pipe 41c from the corresponding processing liquid tank 41a is adjusted. The amount of the processing liquid flowing through each individual delivery pipe 41b is detected by the corresponding flow meter 41e. Additionally, a system and a method for producing the processing liquid stored in each processing liquid tank 41a are not limited to specific ones.

The processing liquid holding unit 42 approaches the substrate W and holds the processing liquid between the substrate W and the processing liquid holding unit 42. The processing liquid holding unit 42 has a circular shape with a diameter larger than that of the substrate W and is provided with a wall standing on a side opposite to the rotor 10 at a peripheral edge of the processing liquid holding unit 42, thereby forming a tray shape. The processing liquid holding unit 42 has a double structure in order to achieve both heat resistance and liquid resistance. That is, in the processing liquid holding unit 42, a base body is formed of a heat-resistant material, and its surroundings are covered with a material that is resistant to the processing liquid. For example, the processing liquid holding unit 42 may be configured by using quartz as the base body and forming a cover of fluorine-based resin such as PTFE or PCTFE around the base. An outer bottom surface of the processing liquid holding unit 42 faces the substrate W.

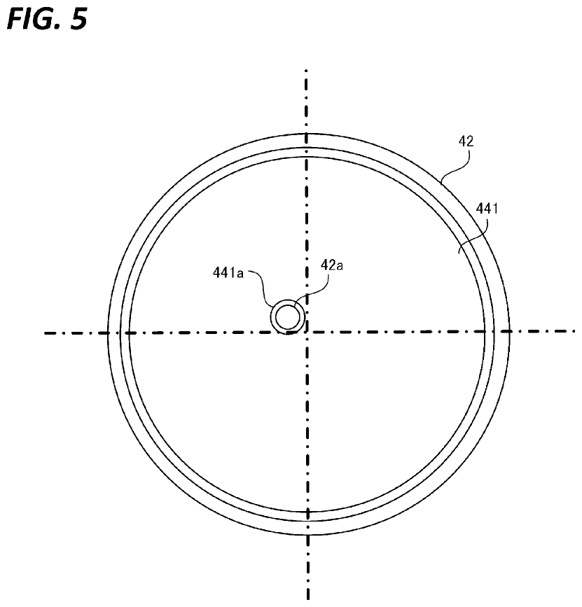

In the processing liquid holding unit 42, an ejection port 42a is formed, through which the front end of the processing liquid supply pipe 41c is inserted and passed and is exposed to the substrate W. The ejection port 42a is deviated from an axis of rotation of the rotor 10, as illustrated in FIG. 5. This is to contribute to equalization of the temperature of the processing liquid by successively changing the portion of the substrate W facing the ejection port 42a as the substrate W rotates.

The lift mechanism 43 is a mechanism for moving the processing liquid holding unit 42 in directions where the processing liquid holding unit 42 contacts and separates from the the substrate W. As the lift mechanism 43, various mechanisms that move the processing liquid holding unit 42 in a direction parallel to an axis of the rotor 10, such as a cylinder or a ball screw mechanism, may be applied, but details thereof will be omitted.

Between the processing liquid holding unit 42 standing by above and the facing surface 111, a gap D1 is formed, into which the substrate W supported by the robot hand 210 may be carried and which does not interrupt ejection of the second processing liquid by the second processing liquid supply unit 50 to be described later. The lift mechanism 43 lowers the processing liquid holding unit 42 to a position where a gap D2 is formed between the processing liquid holding unit 42 and the surface of the substrate W. The gap D2 is, for example, 4 mm or less, so that the processing liquid holding unit 42 and the substrate W remain in a non-contact manner to allow the processing liquid to flow therethrough.

The heating unit 44 heats the processing liquid that is supplied onto the processing target surface of the substrate W by the first processing liquid supply unit 40. The heating unit 44 includes a heater 441 installed on a surface opposite to a surface of the processing liquid holding unit 42 facing the substrate W. Accordingly, the heating unit 44 is raised and lowered with respect to the substrate W by the lift mechanism 43, together with the processing liquid holding unit 42. The heater 441 is in the form of a circular sheet. The heater 441 includes, for example, three heater pieces whose heating values are individually controllable. That is, two toroidal heater pieces are concentrically disposed on an outer side of a circularly shaped heater piece. With the heater 441, by individually controlling heating values of the three heater pieces that are concentrically disposed, the temperature of the processing liquid may be changed for each concentric portion. Furthermore, the diameter of the heating unit 44 may be equal to or larger than a diameter of the substrate W, in order to suppress a decrease in temperature in an outer periphery of the substrate W.

The heater 441 is provided with a through-hole 441a through which the processing liquid supply pipe 41c is inserted and passed. A position of the through-hole 441a is continuous and overlaps with the ejection port 42a of the processing liquid holding unit 42 and deviates from the axis of the rotor 10. Additionally, the processing liquid is heated to a preset temperature by a heating device (not illustrated) in the first processing liquid supply unit 40 and is supplied to the substrate W and heated by the heating unit 44. Accordingly, the processing liquid supplied to the substrate W may be spread widely over an entire surface of the substrate W while maintaining the preset temperature. Particularly, by setting the heater 441 on the outer periphery of the substrate W to a high temperature, the effect of raising the temperature in the outer periphery of the substrate W, which is prone to a decrease in temperature, is obtained.

### (Second Processing Liquid Supply Unit)

The second processing liquid supply unit 50 supplies the second processing liquid for oxidation to the processing target surface of the substrate W and thus, performs oxide film formation. The supplying of the second processing liquid is performed consecutively to the above-described etching. The second processing liquid supply unit 50 has supply nozzles 51 and mass flow controllers (hereinafter, referred to as MFC) 52.

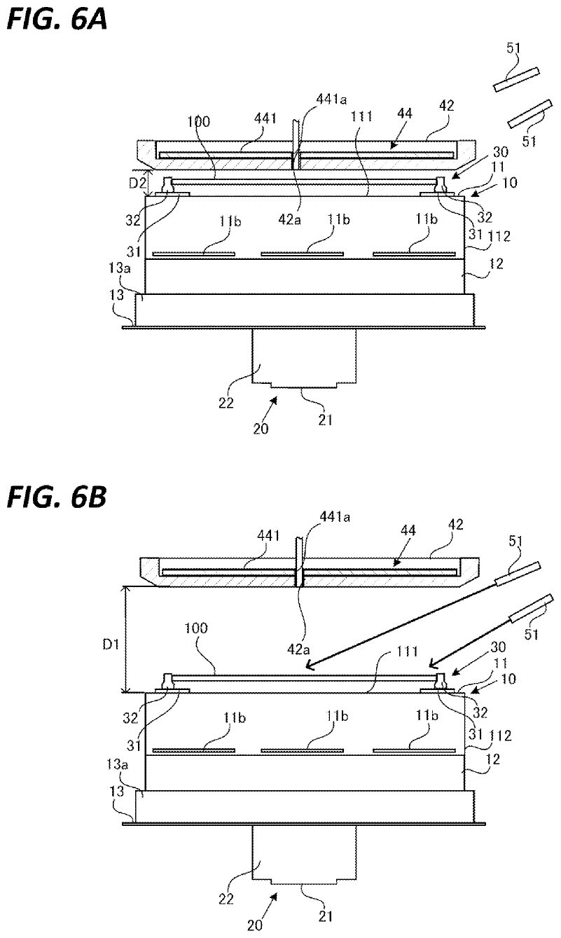

The supply nozzle 51 supplies hydrogen peroxide, which serves as the second processing liquid. Additionally, as the second processing liquid, ozone water may also be used as described above. As illustrated in FIGS. 6A and 6B, the supply nozzle 51 is installed in a position where it does not interfere with the processing liquid holding unit 42 that is raised and lowered, in the vicinity of an outer edge of the rotor 10 in the chamber 1a. A pair of supply nozzles 51 are installed and disposed such that a tip of one supply nozzle faces a center of the substrate W and a tip of the other supply nozzle faces the outer periphery of the substrate W.

The MFC 52 is an adjuster that individually adjusts the supply amount per unit time of the second processing liquid to a pipe connected between a second processing liquid supply device and the supply nozzle 51. The MFC 52 has a mass flow meter that measures a flow rate of a fluid and a solenoid valve that controls the flow rate.

### (Control Unit)

The control unit 60 controls each part of the substrate processing apparatus 1. In order to realize various functions of the substrate processing apparatus 1, the control unit 60 includes a processor that executes programs, a memory that stores various kinds of information such as programs or operating conditions, and a driving circuit that drives each element. That is, the control unit 60 controls the rotation mechanism 20, the processing liquid supply mechanism 41, the lift mechanism 43, the heating unit 44, and the MFC 52.

The control unit 60 of this embodiment perform control such that etching is performed by causing the processing liquid supply mechanism 41 to supply the first processing liquid to the processing target surface of the substrate W while causing the rotation mechanism 20 to rotate the substrate W together with the rotor 10. In addition, as illustrated in FIG. 6B, consecutively to the etching, the control unit 60 perform control such that oxide film formation is performed by causing the second processing liquid to be ejected toward the center and the outer periphery of the rotating substrate W from the supply nozzle 51. The supply amount of the second processing liquid may be controlled by enabling the control unit 60 to control the MFC 52. That is, the control unit 60 perform control such that etching is performed by causing the heating unit 44 to approach the substrate W to heat the first processing liquid while causing the first processing liquid to be ejected from the ejection port 42a, and consecutively to the etching, the heating unit is separated and the second processing liquid is ejected toward the center of the substrate W from the supply nozzle 51.

### [Operations]

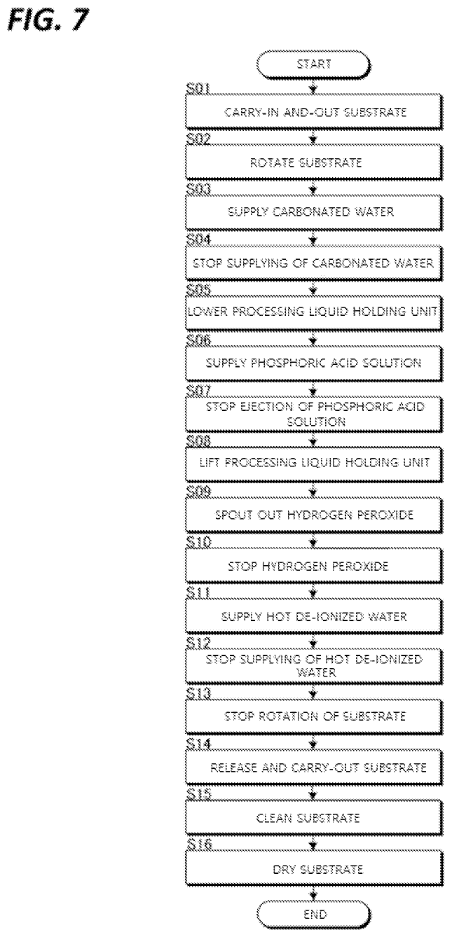

The operations of the substrate processing apparatus 1 of this embodiment as described above will be described with reference to the flow chart of FIG. 7, in addition to FIGS. 1 to 6 above. Also, a substrate processing method for processing the substrate W in the following sequence is also one aspect of this embodiment.

First, as illustrated in FIG. 3, the processing liquid holding unit 42 of the first processing liquid supply unit 40 is in an upper standby position. At this time, the gap D1 is formed between the processing liquid holding unit 42 and the facing surface 111, in which the substrate W supported on the robot hand 210 (see FIG. 1) of the transfer device 200 may be carried. In addition, between a back surface of the substrate W and the facing surface 111, a gap d1 is formed, in which the robot hand 210 supporting the substrate W may be inserted. That is, there is no interruption when the robot hand 210 is inserted between the back surface of the substrate W and the rotor 10 when the substrate W is carried in and out.

Furthermore, by applying electric power to the heater 441 in advance, the surface opposite to the surface of the processing liquid holding unit 42 facing the substrate W is heated, so that the processing liquid holding unit 42 is maintained at a predetermined temperature (e.g., a temperature within a temperature range of 180° C. to 225° C.).

In this state, as illustrated in FIG. 3, the substrate W mounted on the robot hand 210 is carried between the processing liquid holding unit 42 and the rotor 10 and as illustrated in FIG. 4A, peripheral edges of the substrate W are supported by a plurality of holding pins 32, so that the substrate W is held on the facing surface 111 of the rotor 10 (step S01). At this time, the center of the substrate W and the axis of rotation of the rotor 10 are positioned to coincide with each other.

Continuously, the rotor 10 rotates at a predetermined speed which is a relatively high speed (e.g., about 200 rpm to 300 rpm). Accordingly, the substrate W rotates at said predetermined speed together with the holding unit 30 (step S02). Then, carbonated water is supplied to the surface of the substrate W from the ejection port 42a of the processing liquid holding unit 42 (step S03). When carbonated water is supplied to the surface of the rotating substrate W, since the carbonated water moves sequentially toward the outer periphery of the substrate W, the surface of the substrate W is cleaned. When a predetermined time has elapsed, the processing liquid holding unit 42 stops the supplying of the carbonated water (step S04).

The processing liquid holding unit 42 is lowered to a position where a predetermined gap D2 (e.g., 4 mm or less) is formed between the surface of the substrate W and the processing liquid holding unit 42, as illustrated in FIG. 6A (step S05). As the rotor 10 rotates at a predetermined speed (about 50 rpm), which is a relatively low speed, a phosphoric acid solution is supplied from the ejection port 42a of the processing liquid holding unit 42 to the gap between the processing liquid holding unit 42 and the surface of the substrate W while the substrate W rotates at a low speed (step S06). In this manner, the phosphoric acid solution supplied between the processing liquid holding unit 42 and the surface of the substrate W is heated to a high temperature by the processing liquid holding unit 42 that is heated by the heater 441.

In this state, when the phosphoric acid solution is consecutively supplied from the ejection port 42a of the processing liquid holding unit 42, the phosphoric acid solution sequentially moves toward the outer periphery of the substrate W on the surface of the substrate W, and the carbonated water on the surface of the substrate W is substituted with phosphoric acid, so that a portion of the nitride film 103 is etched and removed, as illustrated in FIG. 2B. When a predetermined time has elapsed, the processing liquid holding unit 42 stops the supplying of the phosphoric acid solution (step S07).

Next, as illustrated in FIG. 6B, the processing liquid holding unit 42 rises to a position where a predetermined gap D1 is formed between the processing liquid holding unit 42 and the surface of the substrate W (step S08). Then, the second processing liquid supply unit 50 spouts out hydrogen peroxide toward the center and the outer periphery of the rotating substrate W from the supply nozzle 51 (step S09). The hydrogen peroxide spouted out toward the center of the substrate W sequentially moves toward the outer periphery of the substrate W, and thus, the oxide film 102 is formed as the phosphoric acid solution on the surface of the substrate W is substituted with the hydrogen peroxide. That is, as illustrated in FIG. 2C, the oxide film 102 is formed in a portion where the oxide film 102 has been removed by etching. Additionally, the oxide film 102 is formed even in a portion where the oxide film 102 was not present. When a predetermined time has elapsed, the supply nozzle 51 stops the supplying of hydrogen peroxide (step S10).

Next, the rotor 10 rotates at a predetermined speed which is a relatively high speed (e.g., about 200 rpm to 300 rpm), and the processing liquid holding unit 42 supplies hot de-ionized water to the surface of the substrate W from the ejection port 42a (step S11). When the hot de-ionized water is supplied to the surface of the rotating substrate W, the hot de-ionized water sequentially moves toward the outer periphery of the substrate W and substitutes for the hydrogen peroxide and phosphoric acid on the surface of the substrate W. Then, when a predetermined time has elapsed, the processing liquid holding unit 42 stops the supplying of hot de-ionized water (step S12).

The rotation of the substrate W is stopped (step S13), the robot hand 210 is inserted under the substrate W, and as illustrated in FIG. 4B, the holding of the substrate W by the holding unit 30 is released and the substrate W is carried out by the robot hand 210 (step S14).

Thereafter, the transfer device 200 carries the etched substrate W into the cleaning device 120 and in the chamber 1a, sequentially applies the APM, DIW, and IPA to the rotating substrate W, thereby performing cleaning (step S15). Additionally, the transfer device 200 carries out the substrate W that has been cleaned from the cleaning device 120 and carries the cleaned substrate W into the drying device 300. The drying device 300 performs a drying process by heating the cleaned substrate W while rotating the substrate W (step S16).

### [Effect]

(1) The substrate processing apparatus 1 of this embodiment as described above includes the rotor 10 that holds and rotates the substrate W, the first processing liquid supply unit 40 that supplies the first processing liquid for etching to the processing target surface of the substrate W that is being rotated by the rotor 10, thereby etching the processing target surface, and the second processing liquid supply unit 50 that supplies the second processing liquid for oxidation to the processing target surface of the substrate W that is being rotated by the rotor 10, thereby forming an oxide film, consecutively to the etching by the supplying of the first processing liquid.

In the substrate processing method of this embodiment, the substrate W is held and rotated by the rotor 10, the first processing liquid for etching is supplied to the processing target surface of the substrate W that is being rotated by the rotor 10, and the second processing liquid for oxide film formation is supplied to the processing target surface of the substrate W that is being rotated by the rotor 10.

For this reason, the oxide film 102 may be formed in a portion where the oxide film 102 has been removed by the etching, and in a portion where the oxide film 102 was originally not present, thereby preventing the exposure of a target protective layer. Accordingly, in various subsequent processes, the target protective layer is protected by the oxide film 102. Therefore, the occurrence of product defects may be reduced.

(2) This embodiment includes a cleaning liquid supply that supplies a cleaning liquid to the processing target surface, thereby cleaning the processing target surface, consecutively to the forming the oxide film. Since the oxide film formation is performed consecutively to the etching, even when cleaning is performed, the oxide film 102 serves as a protective film, thereby protecting the target protective layer. For example, when cleaning is performed with hot de-ionized water in the common chamber 1a after the etching, the oxide film 102 formed before the cleaning prevents the polysilicon 101 from being scraped by the cleaning.

(3) The substrate processing apparatus includes the chamber 1a (the first chamber) that accommodates the rotor 10 and performs the etching the processing target surface and the forming the oxide film, and the cleaning device 120 for cleaning the processing target surface having the oxide film 102 formed by the supplying of the second processing liquid, in the other chamber 1a (the second chamber) different from the first chamber. Since the forming of the oxide film is performed consecutively to the etching, even when cleaning is performed by the cleaning device 120, the oxide film 102 serves as a protective film and the target protective layer is protected. For example, even when the substrate is carried out from the etching device 110 and cleaned by the APM in the other chamber 1a of the cleaning device 120, the oxide film 102, which has already been formed, prevents the polysilicon 101 from being scraped by the cleaning.

(4) The first processing liquid supply unit 40 includes the ejection port 42a for ejecting the first processing liquid to the substrate W, the heating unit 44 for heating the first processing liquid supplied onto the processing target surface of the substrate W, and the lift mechanism 43 for raising and lowering the heating unit 44 with respect to the substrate W. The second processing liquid supply unit 50 includes the supply nozzle 51 for supplying the second processing liquid toward the center of the processing target surface. The control unit 60 (for controlling the first processing liquid supply unit 40 and the second processing liquid supply unit 50) perform control such that etching is performed by causing the heating unit 44 to approach the substrate W to heat the first processing liquid while causing the first processing liquid to be ejected from the ejection port 42a, and consecutively to the etching, the heating unit 44 is separated, and the second processing liquid is ejected from the supply nozzle 51, toward the center of the processing target surface of the substrate W.

In this manner, the second processing liquid is supplied toward the center of the rotating substrate W consequently to the etching by supplying the heated first processing liquid, and thus, the second processing liquid is efficiently and widely spread over the overall processing target surface, so that oxide film formation may be performed at high speed. In this embodiment, there is also the supply nozzle 51 for the supply to the outer periphery of the substrate W. By the supply nozzle 51, the second processing liquid may be supplied to the outer periphery of the substrate W before reaching the outer periphery from the center thereof, so that oxide film formation may be performed at a higher speed.

### (Modification)

(1) A heating unit may be installed to heat the second processing liquid before supplying the second processing liquid to the processing target surface. As the heating unit, a heater may be installed, for example, to heat a supply tank or piping of the second processing liquid supply device. Accordingly, even when the amount of the second processing liquid supplied is the same, a rate of formation of the oxide film 102 may be accelerated. In addition, by connecting the supplying unit that supplies the second processing liquid to the processing liquid supply mechanism 41, to the processing liquid supply pipe 41c through the individual delivery pipes 41b, the second processing liquid may be supplied from the ejection port 42a of the processing liquid holding unit 42. Even in this case, the second processing liquid heated by the heating unit 44 may be supplied to the substrate W. In addition, when the heating by the heating unit 44 is insufficient, a heater may be installed on the supplying unit to pre-heat the liquid.

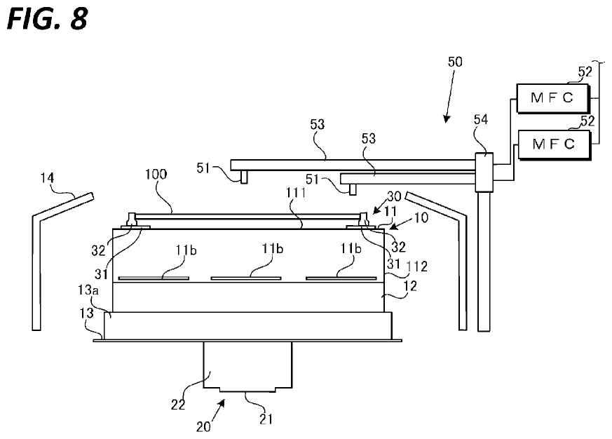

(2) The form of the second processing liquid supply unit 50 is not limited to the supply nozzle 51 as described above. The supply nozzle 51 for the supply to an outer periphery of the processing target surface may be omitted. For example, as illustrated in FIG. 8, a swinging mechanism 54 may be installed to move a pair of swinging arms 53 (each swinging arm 53 having a front end at which the supply nozzle 51 is installed) to a supply position which faces the center and the outer periphery of the processing target surface of the substrate W and to a retreat position which is retreated from the supply position and which allows for carrying-in and carrying-out of the substrate W. In this case, it is also possible to use only the swinging arm 53 that supplies the second processing liquid to the center of the processing target surface.

(3) The processing contents and the processing liquid of the substrate processing apparatus 1 are not limited to those illustrated above. The substrate W and film to be processed are also not limited to the above examples.

From the foregoing, it will be understood that various embodiments of the present disclosure are described herein for purposes of illustration, and that various changes may be made without departing from the scope and idea of the present disclosure. Accordingly, the various embodiments disclosed herein are not intended to limit the true scope and idea designated by the following claims.

What is claimed is:

1. A substrate processing apparatus comprising:
a rotor configured to hold and rotate a substrate;
a first processing liquid supply configured to supply a first processing liquid for etching to a processing target surface of the substrate that is being rotated by the rotor, thereby etching the processing target surface; and
a second processing liquid supply configured to supply a second processing liquid for oxidation to the processing target surface of the substrate that is being rotated by the rotor, thereby forming an oxide film, consecutively to the etching by the supplying of the first processing liquid.

2. The substrate processing apparatus according to claim 1, further comprising:
a cleaning liquid supply configured to supply a cleaning liquid to the processing target surface of the substrate, thereby cleaning the processing target surface, consecutively to the forming the oxide film.

3. The substrate processing apparatus according to claim 1 further comprising:
a first chamber configured to accommodate the rotor and perform the etching the processing target surface and the forming the oxide film; and
a second chamber different from the first chamber and configured to clean the processing target surface having the oxide film formed by the supplying of the second processing liquid.

4. The substrate processing apparatus according to claim 1, wherein the first processing liquid supplied by the first processing liquid supply includes phosphoric acid.

5. The substrate processing apparatus according to claim 4, wherein the processing target surface of the substrate includes a nitride film and an oxide film, and
the etching is targeted at the nitride film.

6. The substrate processing apparatus according to claim 1, wherein the second processing liquid supplied by the second processing liquid supply includes hydrogen peroxide or ozone water.

7. The substrate processing apparatus according to claim 4, wherein the second processing liquid supplied by the second processing liquid supply includes hydrogen peroxide or ozone water.

8. The substrate processing apparatus according to claim 1, further comprising:
a heater configured to heat the second processing liquid before supplying the second processing liquid to the processing target surface.

9. The substrate processing apparatus according to claim 1, wherein the second processing liquid supply includes:
a first supply nozzle configured to supply the second processing liquid toward a center of the processing target surface of the substrate that is being rotated by the rotor, and
a second supply nozzle configured to supply the second processing liquid toward an outer periphery of the processing target surface of the substrate that is being rotated by the rotor.

10. The substrate processing apparatus according to claim 9, wherein the second processing liquid supply includes,
a first swinging arm having a front end at which the first supply nozzle is installed,
a second swinging arm having a front end at which the second supply nozzle is installed, and
a swinging base configured to swing the first swinging arm and the second swinging arm to move the first supply nozzle and the second supply nozzle between a supply position facing the processing target surface of the substrate and a retreat position retreated from the supply position.

11. The substrate processing apparatus according to claim 1, wherein the first processing liquid supply includes:
a processing liquid holder configured to hold a processing liquid between the processing liquid holder and the substrate when approaching the substrate held on the rotor;
a lift configured to raise and lower the processing liquid holder with respect to the substrate;
a heater installed on a surface opposite to a surface of the processing liquid holder facing the substrate held on the rotor; and
an ejection port formed in the processing liquid holder and configured to eject the first processing liquid to the processing target surface of the substrate, and
wherein the second processing liquid supply is configured to supply the second processing liquid to the processing target surface of the substrate from the ejection port.

12. The substrate processing apparatus according to claim 1, wherein the first processing liquid supply includes:
an ejection port configured to eject the first processing liquid to the processing target surface of the substrate;
a heater configured to heat the first processing liquid supplied onto the processing target surface of the substrate; and
a lift configured to raise and lower the heater with respect to the substrate,
wherein the second processing liquid supply includes a supply nozzle configured to supply the second processing liquid toward a center of the processing target surface of the substrate,
wherein the substrate processing apparatus further comprises a controller configured to control the first processing liquid supply and the second processing liquid supply,
wherein the controller controls the first processing liquid supply and the second processing liquid supply such that the etching is performed by causing the heater to approach the substrate to heat the first processing liquid while ejecting the first processing liquid from the ejection port, and consecutively to the etching, the heater is separated, and the second processing liquid is ejected from the supply nozzle toward the processing target surface of the substrate.

13. A substrate processing method comprising:
performing an etching process and an oxide film formation process, consecutively to the etching process, on a processing target surface of a substrate that is being rotated by a rotor while holding and rotating the substrate by the rotor,
wherein, in the etching process, a first processing liquid is supplied to the processing target surface of the substrate, and
wherein, in the oxide film formation process, a second processing liquid is supplied to the processing target surface of the substrate.

14. The substrate processing method according to claim 13, further comprising:
consecutively to the oxide film formation process, performing a cleaning liquid supply process for supplying a cleaning liquid to the processing target surface of the substrate.

15. The substrate processing method according to claim 14, wherein, the etching process, the oxide film formation process, and the cleaning liquid supply process are performed in a first chamber that accommodates the rotor, and
wherein the substrate processing method further comprises,
transferring the substrate from the first chamber to a second chamber, after the cleaning liquid supply process, and
in the second chamber, cleaning the processing target surface of the substrate having an oxide film formed by the oxide film formation process.

16. The substrate processing method according to claim 13, wherein the first processing liquid includes phosphoric acid.

17. The substrate processing method according to claim 13, wherein the second processing liquid includes hydrogen peroxide or ozone water.

18. The substrate processing method according to claim 13, wherein, in the etching process, the first processing liquid is heated by causing a heater to approach the substrate.
